(19) United States
(12) Patent Application Publication
(10) Pub. No.: US 2018/0074311 A1
(43) Pub. Date: Mar. 15, 2018

(54) ENHANCED ILLUMINATION EFFICIENCY IN MASKLESS, PROGRAMMABLE OPTICAL LITHOGRAPHY SYSTEMS

(71) Applicant: Applied Materials, Inc., Santa Clara, CA (US)

(72) Inventors: Edward BUDIARTO, Fremont, CA (US); Mehdi VAEZ-IRAVANI, Los Gatos, CA (US); Christopher BENCHER, Cupertino, CA (US)

(21) Appl. No.: 15/552,064

(22) PCT Filed: May 14, 2015
(86) PCT No.: PCT/US2015/030748

§ 371 Date: Aug. 18, 2017

Related U.S. Application Data
(60) Provisional application No. 62/119,043, filed on Feb. 20, 2015.

(51) Int. Cl. G02B 26/08; G02B 5/08; G03F 7/20

(52) U.S. Cl. CPC G02B 26/0833; G03F 7/7015; G02B 5/0833

(57) ABSTRACT

Embodiments described herein generally relate to a DMD. The DMD includes a base and a plurality of mirrors disposed on the base. Each mirror of the plurality of mirrors has a surface facing away from the base, and a structure is disposed on the surface of each mirror. The structure enhances the reflectance of the surface of each mirror, which enhances the efficiency of light manipulation and delivery.

### BACKGROUND

### Field

Embodiments described herein generally relate to apparatus for microlithography patterning and more particularly to a digital micro-mirror device (DMD).

### Description of the Related Art

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels may comprise a layer of liquid crystal material forming pixels sandwiched between two plates. When power from the power supply is applied across the liquid crystal material, an amount of light passing through the liquid crystal material may be controlled at pixel locations enabling images to be generated.

Microlithography techniques are generally employed to create electrical features incorporated as part of the liquid crystal material layer forming the pixels. According to this technique, a light-sensitive photoresist is typically applied to at least one surface of the substrate. Then, a pattern generator, such as a programmable writing engine in the form of a digital micro-mirror device (DMD), exposes selected areas of the light-sensitive photoresist as part of a pattern with light to cause chemical changes to the photoresist in the selective areas to prepare these selective areas for subsequent material removal and/or material addition processes to create the electrical features.

Insufficient light delivery to the selected areas can cause secondary effects, such as stray light and excess heating of various elements in the system. Therefore, an improved DMD is needed.

### SUMMARY

Embodiments described herein generally relate to a DMD. The DMD includes a base and a plurality of mirrors disposed on the base. Each mirror of the plurality of mirrors has a surface facing away from the base, and a structure is disposed on the surface of each mirror. The structure enhances the reflectance of the surface of each mirror, which enhances the efficiency of light manipulation and delivery.

In one embodiment, a DMD includes a base and a plurality of mirrors disposed on the base. Each mirror of the plurality of mirrors includes a surface that is facing away from the base. The DMD further includes a structure disposed on the surface of each mirror, and the structure includes one or more pairs of alternating layers of dielectric material.

In another embodiment, a DMD includes a base and a plurality of mirrors disposed on the base. Each mirror of the plurality of mirrors includes a surface that is facing away from the base. The DMD further includes a structure disposed on the surface of each mirror, and the structure includes a first layer of dielectric material disposed on the surface and a second layer of dielectric material disposed on the first layer. A refractive index of the first layer of dielectric material is different from a refractive index of the second layer of dielectric material.

In another embodiment, a DMD includes a base and a plurality of mirrors disposed on the base. Each mirror of the plurality of mirrors includes a surface that is facing away from the base. The DMD further includes a structure disposed on the surface of each mirror, and the structure includes multiple pairs of layers of dielectric material. Each pair of the multiple pairs of layers of dielectric material includes a first layer and a second layer. A refractive index of the first layer of dielectric material is different from a refractive index of the second layer of dielectric material.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 schematically illustrates a DMD according to one embodiment.

FIGS. 2A-2C are schematic side views of a mirror of the DMD of FIG. 1 according to various embodiments.

FIGS. 3A-3B are charts illustrating improvements in reflectance with the DMD of FIG. 1 according to various embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to a DMD. The DMD includes a base and a plurality of mirrors disposed on the base. Each mirror of the plurality of mirrors has a surface facing away from the base, and a structure is disposed on the surface of each mirror. The structure enhances the reflectance of the surface of each mirror, which enhances the efficiency of light manipulation and delivery.

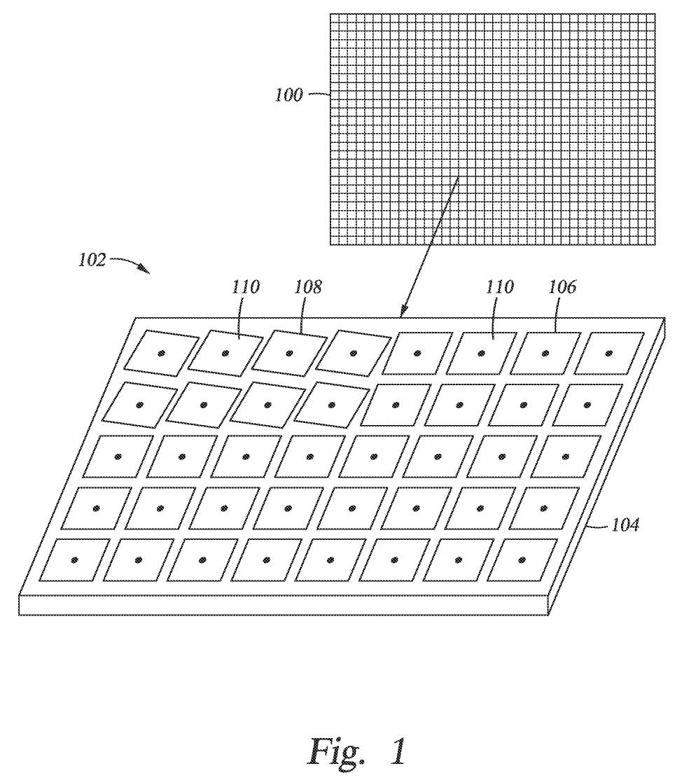

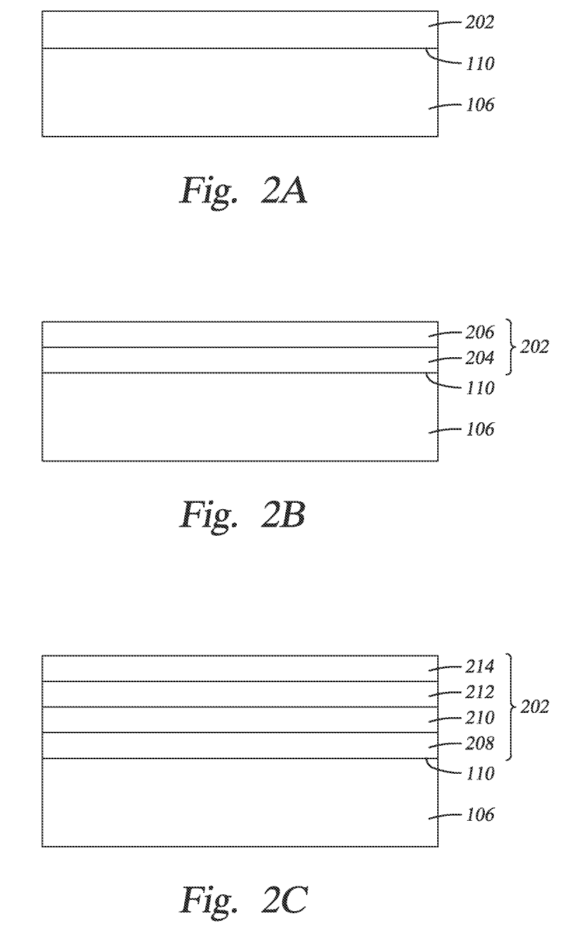

FIG. 1 schematically illustrates a DMD 100 according to one embodiment. The DMD 100 may include a base 104 and plurality of mirrors 106, 108, as shown in an enlarged and simplified portion 102. The plurality of mirrors 106, 108 may be individually controlled to tilt in fixed angles, such as ±12 degrees. As shown in FIG. 1, the mirrors 106 are flat while the mirrors 108 are tilted at an angle by the transistor controller disposed under each mirror 108. The tilting of the mirrors 106, 108 may determine whether the light reflected by the mirrors 106, 108 is directed to a surface of a substrate to be patterned. In one embodiment, the tilted mirrors 108 at +12 degrees direct the light to the surface of the substrate and the titled mirrors 108 at −12 degrees and the flat mirrors 106 direct the light to a light dump, which is not on the surface of the substrate. The plurality of mirrors 106, 108 may each include a surface 110 that is facing away from the base 104. The surface 110 may be made of a reflective metal, such as aluminum, in order to reflect a light, such as a laser beam, from a light source to the surface of the substrate or to the light dump. A structure (shown in FIGS. 2A-2C) may be disposed on the surface 110 in order to increase reflectance of the mirrors 106, 108.

FIGS. 2A-2C are schematic side views of the mirror 106 or mirror 108 of the DMD 100 of FIG. 1 according to various embodiments. As shown in FIG. 2A, the mirror 106 (or mirror 108) has the surface 110 that is facing away from the base 104. A structure 202 may be disposed on the surface 110. In one embodiment, the structure 202 includes a single layer of dielectric material. In other embodiments, the structure 202 is a multi-layer structure including one or more pairs of alternating thin dielectric layers having varying refractive indices. The structure 202 disposed on the surface 110 increases reflectivity and decreases absorption. When absorption of the mirrors 106, 108 is decreased, the heat load on the DMD 100 is also decreased, which in turn enables longer service lifetime of the DMD 100, less cooling for the DMD 100, and higher power illumination into the DMD 100 for higher power applications. The structure 202 formed on the surface 110 is not thick enough to alter the mechanical characteristics of the mirrors 106, 108 of the DMD 100. Additionally, since the structure 202 is made of a dielectric material, no issues should arise in the process of manufacturing the DMD 100.

As shown in FIG. 2B, the structure 202 is a bilayer structure including a first layer 204 disposed on the surface 110 and a second layer 206 disposed on the first layer 204. The refractive index of the first layer 204 is different from the refractive index of the second layer 206. In one embodiment, the imaginary part k of the refractive index of layers 204, 206 may be the same, such as 0, but the real part n of the refractive index of layers 204, 206 may be different, and the difference in n between layers 204, 206 may be at least 1. In one embodiment, the light reflected by the DMD 100 has a wavelength in the ultraviolet (UV) range, such as between about 360 nm and about 410 nm, and the first layer 204 is silicon dioxide and the second layer 206 is titanium dioxide. In another embodiment, the light reflected by the DMD 100 has a wavelength in the visible range, such as between about 400 nm and about 750 nm, and the first layer 204 is magnesium fluoride and the second layer 206 is vanadium (V) oxide. The thickness of the first layer 204 may range from about 40 nm to about 86 nm and the thickness of the second layer 206 may range from about 35 nm to about 60 nm. In one embodiment, the first layer 204 is silicon dioxide and has a thickness of about 40 nm and the second layer 206 is titanium dioxide and has a thickness of about 40 nm. In another embodiment, the first layer 204 is silicon dioxide and has a thickness of about 53 nm and the second layer 206 is titanium dioxide and has a thickness of about 38 nm. In another embodiment, the first layer 204 is silicon dioxide and has a thickness of about 82 nm and the second layer 206 is titanium dioxide and has a thickness of about 58 nm. In another embodiment, the first layer 204 is magnesium fluoride and has a thickness of about 85 nm and the second layer 206 is vanadium (V) oxide and has a thickness of about 47 nm.

FIG. 2C is a schematic side view of the mirror 106 or mirror 108 according to another embodiment. As shown in FIG. 2C, the structure 202 may include a first layer 208 disposed on the surface 110 of the mirror 106 or mirror 108, a second layer 210 disposed on the first layer 208, a third layer 212 disposed on the second layer 210, and a fourth layer 214 disposed on the third layer 212. First and third layers 208, 212 may be made of the same material and may have the same thickness, and second and fourth layers 210, 214 may be made of the same material and may have the same thickness. The refractive index of layers 208, 212 may be different from the refractive index of layers 210, 214. In one embodiment, the imaginary part k of the refractive index of layers 208, 210, 212, 214 may be the same, such as 0, but the real part n of the refractive index of layers 208, 212 may be different from the real part n of the refractive index of layers 210, 214, and the difference in n may be at least 1. Thus, the structure 202 may include two pairs of alternating layers having different refractive indices. The structure 202 may include more than two pairs of alternating layers as long as the thickness of the structure 202 does not alter the mechanical characteristics of the mirrors 106, 108 of the DMD 100.

In one embodiment, the light reflected by the DMD 100 has a wavelength in the ultraviolet (UV) range, such as between about 360 nm and about 410 nm, and the first and third layers 208, 212 are silicon dioxide and the second and fourth layers 210, 214 are titanium dioxide. In another embodiment, the light reflected by the DMD 100 has a wavelength in the visible range, such as between about 400 nm and about 750 nm, and the first and third layers 208, 212 are magnesium fluoride and the second and fourth layers 210, 214 are vanadium (V) oxide. The thickness of the first layer 208 may range from about 40 nm to about 90 nm, the thickness of the second layer 210 may range from about 35 nm to about 90 nm, the thickness of the third layer 212 may range from about 40 nm to about 90 nm, and the thickness of the fourth layer 214 may range from about 35 nm to about 90 nm. In one embodiment, the first and third layers 208, 212 are silicon dioxide and each has a thickness of about 40 nm, and the second and fourth layers 210, 214 are titanium dioxide and each has a thickness of about 40 nm. In another embodiment, the first and third layers 208, 212 are silicon dioxide, and the first layer 208 has a thickness of about 53 nm and the third layer 212 has a thickness of about 67 nm. The second and fourth layers 210, 214 are titanium dioxide, and the second layer 210 has a thickness of about 38 nm and the fourth layer 214 has a thickness of about 37 nm. In another embodiment, the first and third layers 208, 212 are silicon dioxide and each layer 208, 212 has a thickness of about 65 nm, and the second and fourth layers 210, 214 are titanium dioxide and each layer 210, 214 has a thickness of about 86 nm. In another embodiment, the first and third layers 208, 212 are magnesium fluoride and each layer 208, 212 has a thickness of about 88 nm and the second and fourth layers 210, 214 are vanadium (V) oxide and each layers 210, 214 has a thickness of about 47 nm.

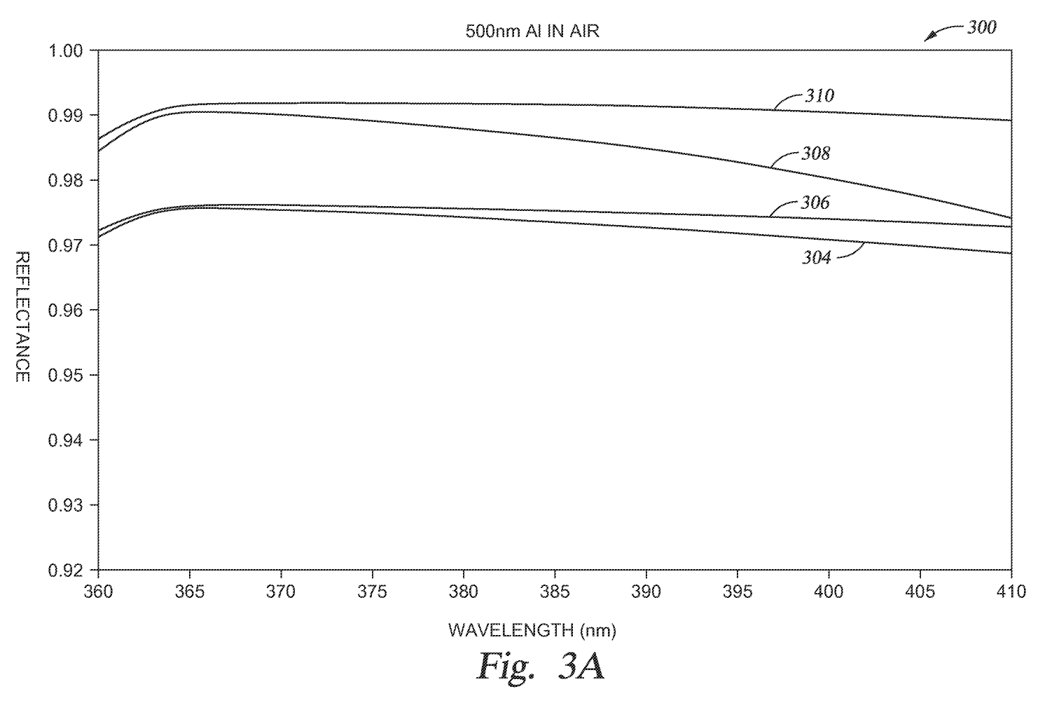

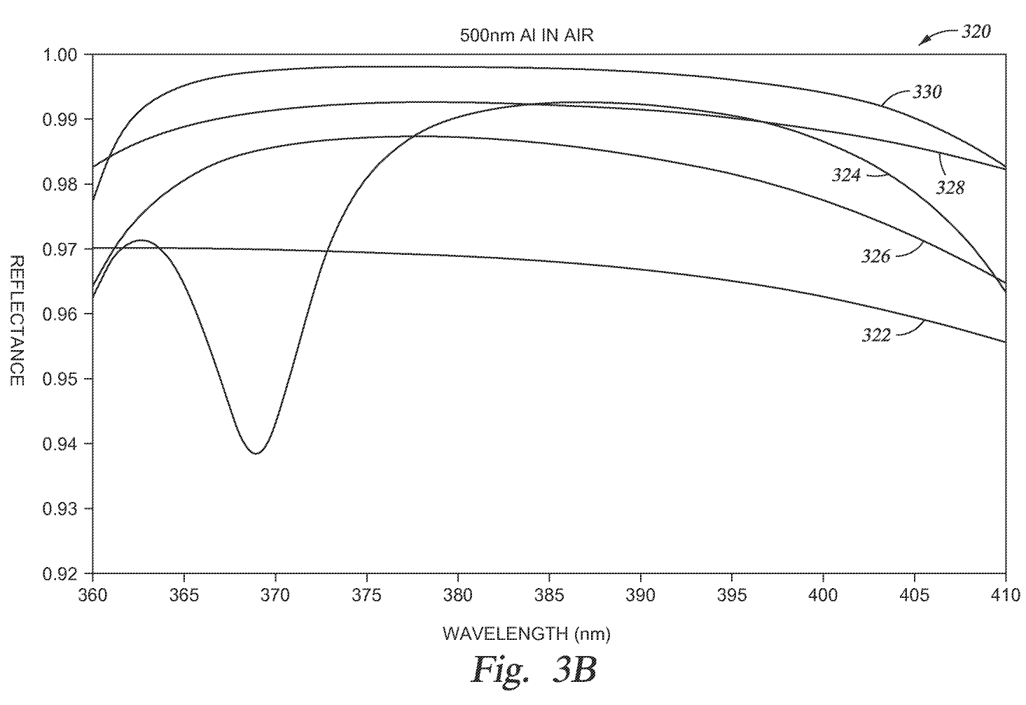

FIG. 3A is a chart 300 illustrating increased reflectance of light having a wavelength between 360 nm and 410 nm, as a result of having the structure 202 disposed on the mirrors 106, 108 of the DMD 100. As shown in FIG. 3A, line 302 indicates the reflectance of a mirror that is made of 500 nm thick aluminum. Lines 304, 306, 308 and 310 indicate the increased reflectance of a mirror that is made of a 500 nm thick aluminum mirror having the structure 202 disposed thereon. For line 304, the structure 202 is a bilayer structure and includes a silicon dioxide layer and a titanium dioxide layer. Each layer has a thickness of about 40 nm. For line 306, the structure 202 is a bilayer structure and includes a silicon dioxide layer and a titanium dioxide layer. The silicon dioxide layer has a thickness of about 53 nm and the titanium dioxide layer has a thickness of about 38 nm. For line 308, the structure 202 includes a first silicon dioxide layer, a first titanium dioxide layer disposed on the first silicon dioxide layer, a second silicon dioxide layer disposed on the first titanium dioxide layer, and a second titanium dioxide layer disposed on the second silicon dioxide layer. Each layer in the structure 202 has a thickness of about 40 nm. For line 310, the structure 202 includes a first silicon dioxide layer, a first titanium dioxide layer disposed on the first silicon dioxide layer, a second silicon dioxide layer disposed on the first titanium dioxide layer, and a second titanium dioxide layer disposed on the second silicon dioxide layer. The first silicon dioxide layer has a thickness of about 53 nm, the first titanium dioxide layer has a thickness of about 38 nm, the second silicon dioxide layer has a thickness of about 67 nm, and the second titanium dioxide layer has a thickness of about 37 nm. The reflectance indicated by lines 304, 306, 308, 310 is consistently higher than the reflectance indicated by line 302 across the entire wavelength range shown in FIG. 3A.

FIG. 3B is a chart 320 illustrating increased reflectance of light having a wavelength between 400 nm and 750 nm, as a result of having the structure 202 disposed on the mirrors 106, 108 of the DMD 100. As shown in FIG. 3B, line 322 indicates the reflectance of a mirror that is made of 500 nm thick aluminum. Lines 324, 326, 328 and 330 indicate the increased reflectance of a mirror that is made of a 500 nm thick aluminum mirror having the structure 202 disposed thereon. For line 324, the structure 202 includes a first silicon dioxide layer, a first titanium dioxide layer disposed on the first silicon dioxide layer, a second silicon dioxide layer disposed on the first titanium dioxide layer, and a second titanium dioxide layer disposed on the second silicon dioxide layer. The first and second silicon dioxide layers each has a thickness of about 65 nm and the first and second titanium dioxide layers each has a thickness of about 86 nm. For line 326, the structure 202 is a bilayer structure and includes a silicon dioxide layer and a titanium dioxide layer. The silicon dioxide layer has a thickness of about 82 nm and the titanium dioxide layer has a thickness of about 58 nm. For line 328, the structure 202 is a bilayer structure and includes a magnesium fluoride layer and a vanadium (V) oxide layer. The magnesium fluoride layer has a thickness of about 85 nm and the vanadium (V) oxide layer has a thickness of about 47 nm. For line 330, the structure 202 includes a first magnesium fluoride layer, a first vanadium (V) oxide layer disposed on the first magnesium fluoride layer, a second magnesium fluoride layer disposed on the first vanadium (V) oxide layer, and a second vanadium (V) oxide layer disposed on the second magnesium fluoride layer. The first and second magnesium fluoride layers each has a thickness of about 88 nm and the first and second vanadium (V) oxide layers each has a thickness of about 47 nm. The reflectance indicated by lines 326, 328, 330 is consistently higher than the reflectance indicated by line 322 across the entire wavelength range shown in FIG. 3B.

While the foregoing is directed to embodiments of the present disclosure, other and further embodiments may be devised without departing from the basic scope thereof, and the scope thereof is determined by the claims that follow.

1. A digital micro-mirror device, comprising:
a base;
a plurality of mirrors disposed on the base, wherein each mirror of the plurality of mirrors includes a surface facing away from the base; and
a structure disposed on the surface of each mirror, wherein the structure includes one or more pairs of alternating layers of dielectric material.

2. The digital micro-mirror device of claim 1, wherein the structure includes one pair of layers of dielectric material.

3. The digital micro-mirror device of claim 2, wherein a refractive index of a layer of the one pair of layers of dielectric material is different from a refractive index of another layer of the one pair of layers of dielectric material.

4. The digital micro-mirror device of claim 3, wherein the one pair of layers of dielectric material includes a silicon dioxide layer disposed on the surface of each mirror and a titanium dioxide layer disposed on the silicon dioxide layer.

5. The digital micro-mirror device of claim 3, wherein the one pair of layers of dielectric material includes a magnesium fluoride layer disposed on the surface of each mirror and a vanadium (V) oxide layer disposed on the magnesium fluoride layer.

6. The digital micro-mirror device of claim 1, wherein the structure includes multiple pairs of layers of dielectric material.

7. The digital micro-mirror device of claim 6, wherein a refractive index of a layer of a pair of layers of the multiple pairs of layers of dielectric material is different from a refractive index of another layer of the pair of layers of the multiple pairs of layers of dielectric material.

8. The digital micro-mirror device of claim 6, wherein each pair of layers of the multiple pairs of dielectric material includes a silicon dioxide layer and a titanium dioxide layer disposed on the silicon dioxide layer.

9. The digital micro-mirror device of claim 6, wherein each pair of layers of the multiple pairs of dielectric material includes a magnesium fluoride layer and a vanadium (V) oxide layer disposed on the magnesium fluoride layer.

10. A digital micro-mirror device, comprising:
a base;
a plurality of mirrors disposed on the base, wherein each mirror of the plurality of mirrors includes a surface facing away from the base; and
a structure disposed on the surface of each mirror, wherein the structure includes a first layer of dielectric material disposed on the surface and a second layer of dielectric material disposed on the first layer, wherein a refractive index of the first layer of dielectric material is different from a refractive index of the second layer of dielectric material.

11. The digital micro-mirror device of claim 10, wherein the first layer of dielectric material is a silicon dioxide layer disposed on the surface of each mirror and the second layer of dielectric material is a titanium dioxide layer disposed on the silicon dioxide layer.

12. The digital micro-mirror device of claim 11, wherein the silicon dioxide layer has a thickness ranging from about 40 nm to about 90 nm and the titanium dioxide layer has a thickness ranging from about 35 nm to about 90 nm.

13. The digital micro-mirror device of claim 10, wherein the first layer of dielectric material is a magnesium fluoride layer disposed on the surface of each mirror and the second layer of dielectric material is a vanadium (V) oxide layer disposed on the magnesium fluoride layer.

14. A digital micro-mirror device, comprising:
a base;
a plurality of mirrors disposed on the base, wherein each mirror of the plurality of mirrors includes a surface facing away from the base; and
a structure disposed on the surface of each mirror, wherein the structure includes multiple pairs of layers of dielectric material, wherein each pair of the multiple pairs of layers of dielectric material includes a first layer and a second layer, and wherein a refractive index of the first layer is different from a refractive index of the second layer.

15. The digital micro-mirror device of claim 14, wherein the first layer has a thickness ranging from about 40 nm to about nm 90 nm and the second layer has a thickness ranging from about 35 nm to about 90 nm.

16. The digital micro-mirror device of claim 14, wherein the first layer is a silicon dioxide layer and the second layer is a titanium dioxide layer.

17. The digital micro-mirror device of claim 14, wherein the first layer is a magnesium fluoride layer and the second layer is a vanadium (V) oxide layer.

18. The digital micro-mirror device of claim 14, wherein the first layers of the multiple pairs of layers of dielectric material have a same thickness and the second layers of the multiple pairs of layers of dielectric material have a same thickness.

19. The digital micro-mirror device of claim 10, wherein the structure further comprises a third layer of dielectric material disposed on the second layer of dielectric material and a fourth layer of dielectric material disposed on the third layer of dielectric material.

20. The digital micro-mirror device of claim 19, wherein the third layer of dielectric material is made of a same material as the first layer of dielectric material and the fourth layer of dielectric material is made of a same material as the third layer of dielectric material.
